(19) United States
(12) Patent Application Publication
(10) Pub. No.: US 2008/0277727 A1
(43) Pub. Date: Nov. 13, 2008

(54) Apparatus and method for electrostatic discharge protection with p-well integrated components

(76) Inventors: Pravin P. Patel, Sugar Land, TX (US); Roger A. Cline, Plano, TX (US); Steven G. Howard, Plano, TX (US); Robert C. Choens, Houston, TX (US)

Correspondence Address: TEXAS INSTRUMENTS INCORPORATED, P O BOX 655474, M/S 3999, DALLAS, TX, 75265, US

(21) Appl. No.: 11/903,427

(22) Filed: Sep. 21, 2007

Related U.S. Application Data
(60) Provisional application No. 60/846,795, filed on Sep. 22, 2006.

(51) Int. Cl. H01L 23/62

(52) U.S. Cl. 257/355; 257/E23.001

(57) ABSTRACT

An electrostatic protection circuit has a transistor for pumping charge into the substrate and a transistor, including a parasitic transistor, for removing charge from the substrate and tabs. The circuit is enclosed by barrier that prevents the migration of charge from the region of the transistors. The added charge in the region of the parasitic transistor, resulting from the increased charge in the region of the parasitic transistor, increases the flow of current between electrodes of the transistor, thereby removing the electrostatic charge more efficiently. removing the electrostatic charge more efficiently.

This Application claims the benefit of Provisional Application 60/846,795, filed Sep. 22, 2007.

### BACKGROUND OF THE INVENTION

1. Field of the Invention

The present invention relates generally to semiconductor components, and more particularly, to protection against electrostatic discharge for semiconductor devices. An electrostatic charge, applied inadvertently to a semiconductor circuit, can not only effect the operation of the semiconductor components, but can damage the semiconductor components themselves.

2. Description of the Related Art

Referring to FIG. 1, the apparatus used to protect a semiconductor circuit, according to the prior art, is shown. Signals are applied to processing components 15 through a plurality of pads, pad 101 shown as an example. The processing components can be a data processing unit, memory unit, or a portion thereof fabricated on a p-substrate. In the embodiment illustrated in FIG. 1, the processing components are fabricated on a p-well 12. Also fabricated on the p-well 12 are components 110 and 120. The pad 101 is also coupled to components 110 and 120. Component 110 includes an n+diffusion 112, an n+ diffusion 113, a p⁺ diffusion 114, and a gate 111. The gate 111 is fabricated between the n+diffusion 112 and n+ diffusion 113 thereby forming a transistor. Component 110 is typically referred to as a pump transistor. In component 120, the pad 101 is connected to n+ diffusion 112 and through capacitor 102 to gate 111. Component 120 includes an n+diffusion 122, an n+ diffusion 123, and a gate 121 fabricated between n+ diffusion 122 and n+diffusion 123 to form a transistor. n+ diffusion 123 is connected to the V_{SS} terminal. Pad 101 is connected to n+ diffusion 122 and is coupled through capacitor 102 to gate 121.

The operation of the circuit of FIG. 1 can be understood as follows. An application of an electrostatic charge applied to pad 101 results in a voltage being applied to gates 111 and 121 causing the transistor structures to conduct. As a result of the conduction of the pump transistor component 110, charge is injected into substrate 12 through p⁺-well 114. The presence of the charge provides a potential to the gate 129 of the parasitic bipolar transistor 127 and the parasitic transistor 127 conducts. The parasitic transistor 127 conducts in parallel with the field effect transistor of component 129. In this manner, the electrostatic charge can be conducted away from the p+-well by the V_{SS} terminal.

As will be clear to those skilled in the art, FIG. 1 shows only single components. In implementing this electrostatic protection technique, an array of transistors will typically be employed to permit the conduction of a sufficient current through the V_{SS} terminal to prevent compromising the accompanying processing circuits.

While the circuit shown in FIG. 1 provides for the removal of electrostatic charge, in practice, the circuit does not conduct with a sufficient magnitude or duration to be satisfactory for removing the electrostatic charge.

A need has been felt for apparatus and an associated method having the feature of improving the protection against electrostatic discharge in semiconductor circuits. It would be another more particular feature of the apparatus and associated method to provide the electrostatic protection circuit with a mechanism for extending the period of electrostatic-origin current removal from the circuit.

### SUMMARY OF THE INVENTION

The aforementioned and other features of the apparatus and associated method are accomplished, according to the present invention, by enclosing the typical electrostatic protection circuit in an electrically isolated well that prevents the migration of electrons, inserted into the substrate, from migrating away from the electrostatic protection circuits. The conduction of the virtual transistor associated with the second transistor is stronger and of longer duration.

Other features and advantages of the present invention will be more clearly understood upon reading of the following description along with the accompanying figures and claims.

### BRIEF DESCRIPTION OF DRAWINGS

FIG. 1 illustrates the apparatus used in conjunction with the processing components according to the prior art.

FIG. 2 illustrates the technique for improving the efficiency of the electrostatic protection circuit according to the present invention.

### DESCRIPTION OF THE PREFERRED EMBODIMENTS

1. Detailed Description of the Drawings

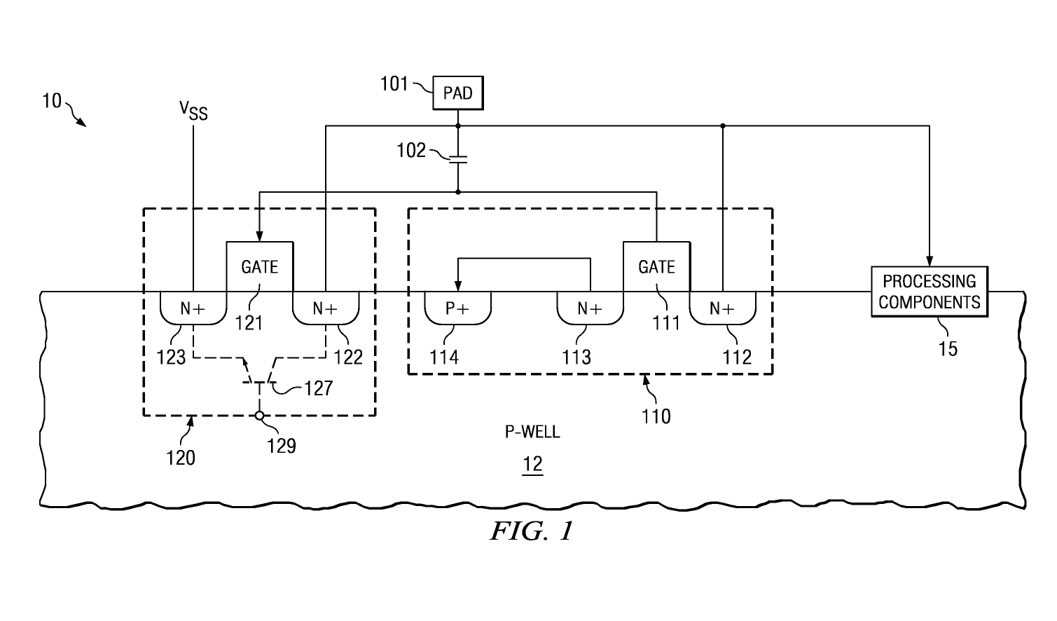

FIG. 1 has been described with respect to the related art.

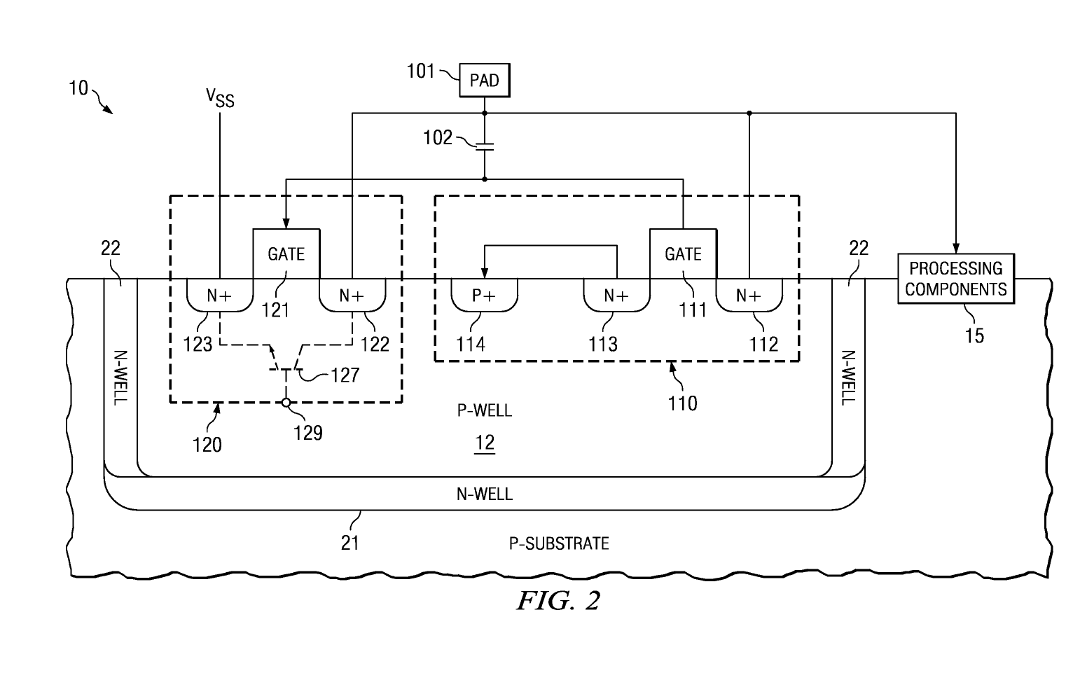

Referring to FIG. 2, the electrostatic protection circuits shown in FIG. 1 is reproduced. In addition, the electrostatic protection circuits are enclosed by a shallow n-well 22 and a deep n-well 21. These n-wells provide electrical isolation between the p-well in which the electrostatic protection circuit is fabricated and the components that are also fabricated in the remainder of the p-substrate 12.

2. Operation of the Preferred Embodiment

The operation of the present invention can be understood as follows. The typical electrostatic protection circuit includes a transistor for pumping charge into the substrate and a transistor applying charge to a pin, the pin conducting the charge away from the integrated circuit. The charge in the substrate results in increased flow of electrons by the biasing of a parasitic bipolar transistor, the parasitic transistor resulting from the two n-wells and the intervening p-substrate for the associated field effect transistor. The charge in the substrate results in the additional current flow between the two p-wells. However, the charge in the substrate is short-lived because of the migration of the inserted charge into other regions of the substrate. By electrically isolating the portion of the substrate into which the charge is pumped from the remainder of the substrate, the activation of the parasitic transistor is stronger and longer lasting than in the absence of the electrical isolation. Consequently, the electrostatic charge is removed more efficiently.

Although the present invention has been described with respect to the preferred embodiment and drawings of the invention, it will be apparent to those skilled in the art that various adaptations, modifications, and alterations may be accomplished without departing from the spirit and scope of the present invention. Accordingly, it is to be understood that the accompanying drawings as set forth hereinabove are not intended to limit the breadth of the present invention, which should be inferred only from the following claims and their appropriately construed legal equivalents.

What is claimed is:

1. An electrostatic charge protection circuit, the circuit comprising:
a substrate;
at least one pump transistor fabricated in the substrate, the pump transistor pumping charge into the substrate;
at least one second transistor fabricated in the substrate, the second transistor having a parasitic bipolar transistor, the second transistor coupled to and transferring charge to an external conductor, the bipolar transistor activated by charge in the substrate; and
a barrier formed in the substrate, the barrier electrically isolating the first and second transistors from the remainder of the substrate.

2. The circuit as recited in claim 1 wherein electrostatic protection circuit is coupled to tabs, the tabs providing an interface for a processing unit.

3. The circuit as recited in claim 2 wherein a tad is coupled to an electrode and a gate of at least one pump transistor and one second electrode.

4. The circuit as recited in claim 1 wherein the electrostatic protection circuit is fabricated on a p-substrate, the barriers being n-well regions.

5. The circuit as recited in claim 4 wherein one electrode of the pump transistor is coupled to a p⁺-well.

6. The circuit as recited in claim 1 wherein charge pumped into the substrate by the pump transistor determines the conduction of the parasitic transistor.

7. A method for improving an electrostatic protection circuit for an integrated processing circuit, the method comprising:
electrically isolating the substrate in which the electrostatic protection circuit is fabricated from the portion of the substrate in which the processing circuit is fabricated.

8. The method as recited in claim 7 further comprising implementing the electrostatic protection circuit with at least one pump transistor for pumping charge into the substrate and with at least one second transistor for applying electrostatic charge to an external conductor, the second transistor having a parasitic transistor associated therewith, the parasitic transistor activated by the charge pumped into the substrate.

9. The method as recited in claim 9 comprising implementing the electrical isolation of the electrostatic protection circuit by surrounding the p-substrate in which the electrostatic protection circuit is fabricated with n-regions.

10. The method as recited in claim 9 further comprising coupling the electrostatic protection circuit to pads wherein the interface pads of the processing circuit are coupled to the electrostatic protection circuit.

11. An integrated circuit fabricated on a substrate, the integrate circuit comprising:
a processing portion fabricated in a substrate, the processing portion having tabs, the tabs permitting transfer of signals to and from the processing portion; and
an electrostatic protection portion, the electrostatic protection portion coupled to at least one of the tabs, electrostatic protection portion causing electrostatic charge applied to the tab to be applied to an external conductor, the substrate portion of the electrostatic protection circuit portion being electrically isolated from the substrate portion of the processing circuit.

12. The integrated circuit as recited in claim 11 wherein the electrostatic protection portion is fabricated on a p-substrate, the electrical isolation being n-regions formed in the p-substrate, the n-regions surrounding the electrostatic protection portion.

13. The integrated circuit as recited in claim 11 wherein the electrostatic protection portion includes:
at least one pump transistor for pumping charge into the substrate; and
at least one second transistor coupled to an external conductor for removing charge from the electrostatic protection portion, the second transistor having a parasitic transistor activated by charge pumped into the substrate.

14. The integrated circuit as recited in claim 13 wherein the electrostatic protection portion further includes a p⁺-well, the p⁺-well coupled to an electrode of the pump transistor.

15. The integrated circuit as recited in claim 13 wherein the tabs are coupled to an electrode and a gate of the pump transistor and of the second transistor.
